(19) United States
(12) Patent Application Publication
(10) Pub. No.: US 2015/0179333 A1
(43) Pub. Date: Jun. 25, 2015

(54) TRANSFORMER AND ADAPTER

(71) Applicant: SAMSUNG ELECTRO-MECHANICS CO., LTD., Suwon (KR)

(72) Inventors: Nak Jun JEONG, Suwon (KR); Jong Woo Kim, Suwon (KR); Sung Yun Han, Suwon (KR); Heung Gyoon Choi, Suwon (KR); Seung Hwan Lee, Suwon (KR); Young Seung Noh, Suwon (KR); Geun Young Park, Suwon (KR)

(73) Assignee: SAMSUNG ELECTRO-MECHANICS CO., LTD., Suwon (KR)

(21) Appl. No.: 14/613,970

(22) Filed: Feb. 4, 2015

Related U.S. Application Data
(63) Continuation of application No. 14/288,877, filed on May 28, 2014.

(30) Foreign Application Priority Data
Dec. 20, 2013 (KR) 10-2013-0160237

(51) Int. Cl. H01F 27/28; H01F 27/32

(52) U.S. Cl. CPC H01F 27/2885; H01F 27/2804; H01F 27/2823; H01F 27/323; H01F 2027/2809

(57) ABSTRACT

A transformer including: a primary coil part including a multilayer substrate in which a plurality of substrates having coil patterns are stacked; a secondary coil part having the number of coil turns different from that of the primary coil part, positioned on at least one of upper and lower surfaces of the multilayer substrate, and including a conductor wire and an insulating material coating the conductor wire; and a shielding part disposed on the primary coil part and including at least one substrate on which a shielding pattern is provided

### CROSS-REFERENCE TO RELATED APPLICATIONS

This application is a continuation application of U.S. patent application Ser. No. 14/288,877, filed May 28, 2014, and is related to and claims the foreign priority benefit of Korean Patent Application No. 10-2013-0160237, filed on Dec. 20, 2013, in the Korean Intellectual Property Office, the disclosures of which are incorporated herein by reference.

### BACKGROUND

### Field

The present disclosure relates to a transformer and an adapter.

The use of portable electronic devices, including portable phones, has become general.

Such portable electronic devices commonly include batteries so that these devices may be operated even in a state in which external power is not supplied thereto. In addition, portable electronic devices include power input terminals so that batteries embedded therein may be charged with commercial mains power.

Meanwhile, since commercial mains power supplies a level of electrical current appropriate for large home appliances, it is not appropriate for a small device such as the portable electronic device. Therefore, in order to use commercial mains power as power for portable electronic devices, a separate adapter is required.

Such an adaptor includes a transformer transforming commercial mains power into a voltage appropriate for a corresponding portable electronic device. Here, the transformer, a component in charge of a main function of the adaptor, determines a size of the adaptor. Therefore, in order to miniaturize the adaptor and improve quality of the adaptor, there is a need to develop a transformer having a simple structure.

### SUMMARY

Some embodiments of the present disclosure may provide a transformer able to be easily miniaturized.

Some embodiments of the present disclosure may also provide an adaptor capable of being miniaturized.

According to some embodiments of the present disclosure, a transformer may include: a primary coil part including a plurality of substrates on which coil patterns are formed; a secondary coil part including an insulated coil; and a shielding part formed on the primary coil part and including one or more substrates on which a shielding pattern is formed.

An area of the shielding pattern may be equal to or greater than that of a coil pattern of the primary coil part adjacent to the shielding pattern.

A width of a curved line forming the shielding pattern may be different from that of a curved line forming a coil pattern of the primary coil part adjacent to the shielding pattern.

The shielding pattern may have an open curved line shape in which a portion thereof is opened.

The shielding pattern may be formed along an edge of the substrate.

The shielding pattern may be formed of a single curved line having a coil shape.

The shielding pattern may be formed of a plurality of curved lines having a coil shape.

The shielding pattern may be connected to the coil pattern of the primary coil part.

The shielding pattern may be connected to a core part.

The shielding part may include: a first shielding part formed on one side of the primary coil part; and a second shielding part formed on the other side of the primary coil part.

The first shielding part may be connected to the second shielding part by via electrodes penetrating through the primary coil part.

The coil pattern of the primary coil part may be formed of a curved line having a coil shape.

The substrates of the primary coil part may include a plurality of via electrodes.

The number of via electrodes of the primary coil part may be the same as or greater than that of substrates forming the primary coil part.

The coil of the secondary coil part may be coated with a triple insulating material.

The transformer may further include a tertiary coil part including one or more substrates on which a coil pattern is formed.

The shielding pattern may be connected to the coil pattern of the tertiary coil part.

The coil turns formed by the coil patterns of the primary coil part may be larger than coil turns formed by the coil of the secondary coil part.

According to some embodiments of the present disclosure, an adaptor may include: a circuit board; and a transformer mounted on the circuit board, wherein the transformer includes: a primary coil part including a plurality of substrates on which coil patterns are formed; a secondary coil part including an insulated coil; and a shielding part formed on the primary coil part and including one or more substrates on which a shielding pattern is formed.

The transformer may be mounted on the circuit board so that the plurality of substrates are disposed perpendicularly to a plane of the circuit board.

The adaptor may further include a filter component mounted on the circuit board.

The filter component may be disposed on one corner of the circuit board, and the transformer may be disposed on the other corner of the circuit board opposing to one corner thereof.

The adaptor may further include a capacitor disposed between the filter component and the transformer.

The adaptor may further include a power output terminal disposed in parallel with the transformer in a length or width direction of the transformer.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exploded perspective view of a transformer according to an exemplary embodiment of the present disclosure;

FIG. 2 is a plan view sequentially illustrating substrates forming a shielding part and a primary coil part illustrated in FIG. 1;

FIG. 3 is an enlarged view of the shielding part and a first substrate of the primary coil part illustrated in FIG. 2;

FIGS. 4 through 8 are plan views illustrating other forms of the shielding part illustrated in FIG. 2;

FIG. 9 is an exploded perspective view of a transformer according to another exemplary embodiment of the present disclosure;

FIG. 10 is a plan view sequentially illustrating substrates forming a first shielding part, a tertiary coil part, a primary coil part, and a secondary shielding part illustrated in FIG. 9;

FIG. 11 is a plan view illustrating another form of the first shielding part, the tertiary coil part, the primary coil part, and the secondary shielding part illustrated in FIG. 9;

FIG. 12 is an enlarged view of the first shielding part and the second shielding part illustrated in FIG. 11;

FIG. 13 is a configuration diagram of an adaptor according to an exemplary embodiment of the present disclosure;

FIG. 14 is a configuration diagram illustrating another form of the adaptor illustrated in FIG. 13; and

FIGS. 15 through 17 are graphs illustrating performance of the transformer according to an exemplary embodiment of the present disclosure

### DESCRIPTION OF EMBODIMENTS

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

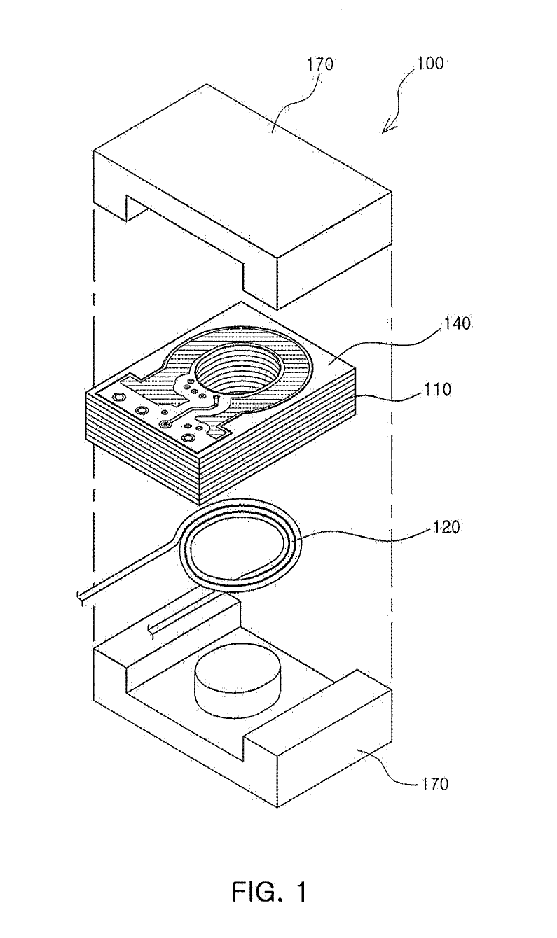

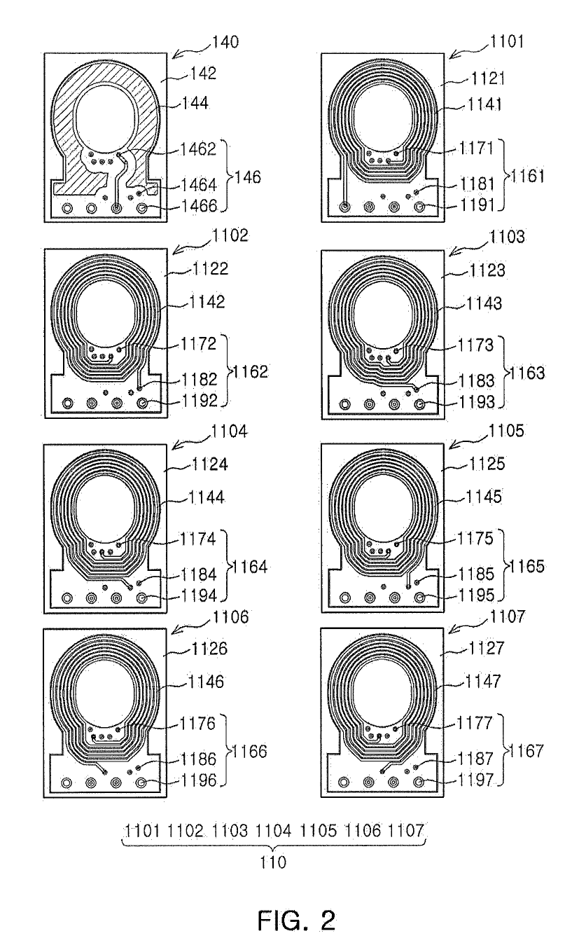

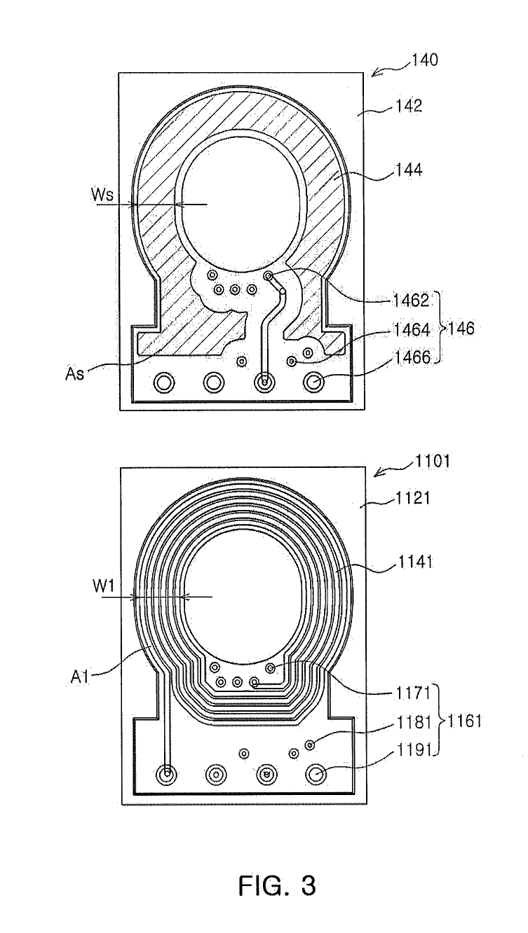

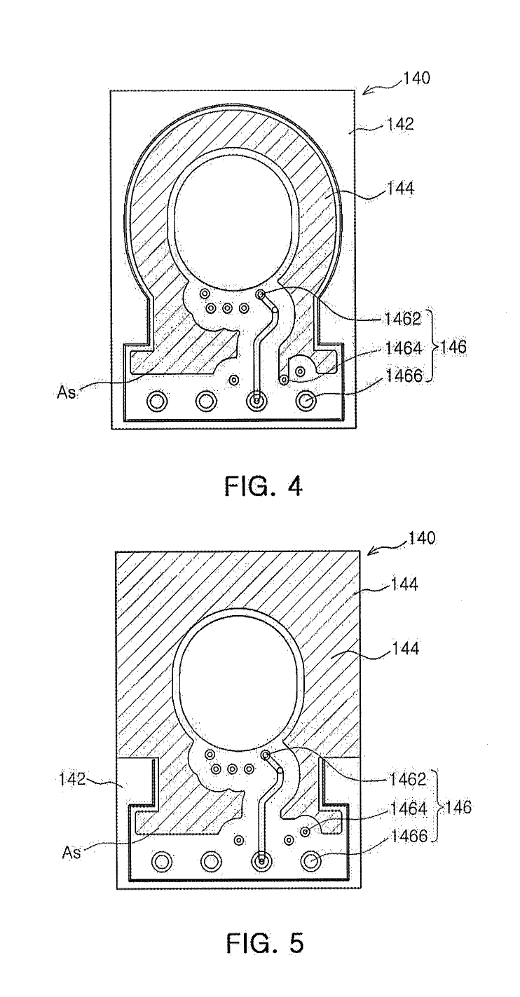

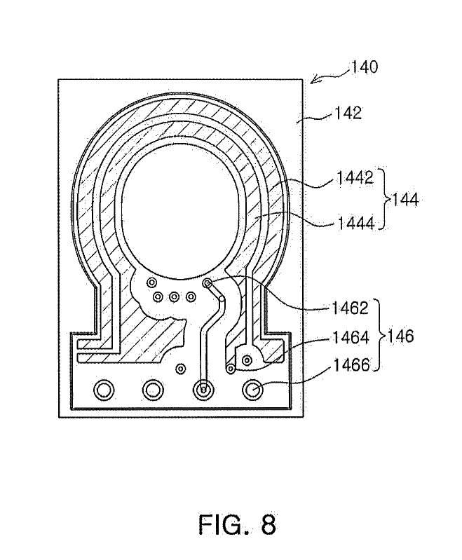

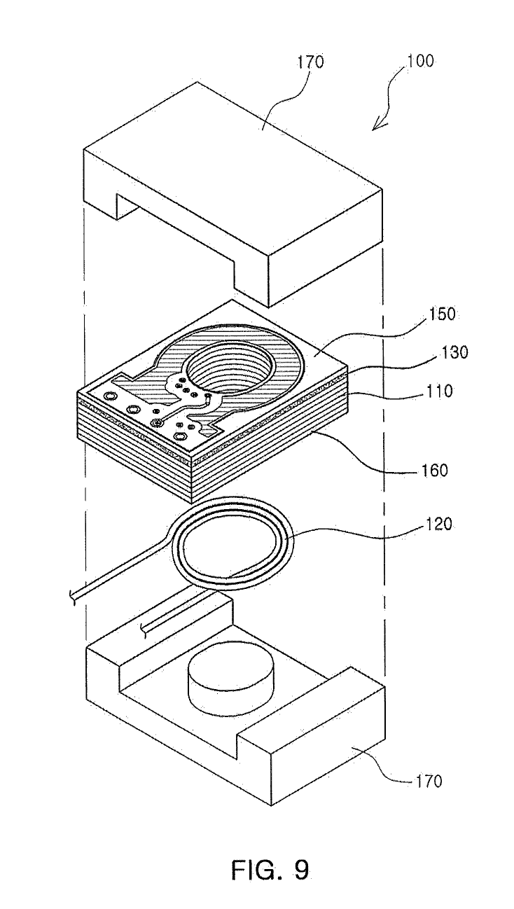

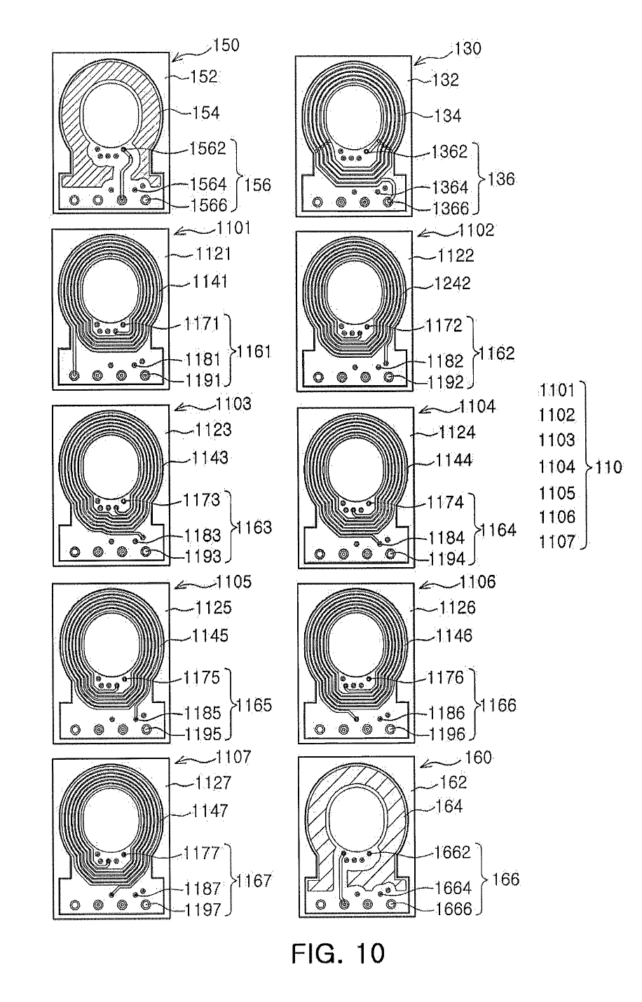

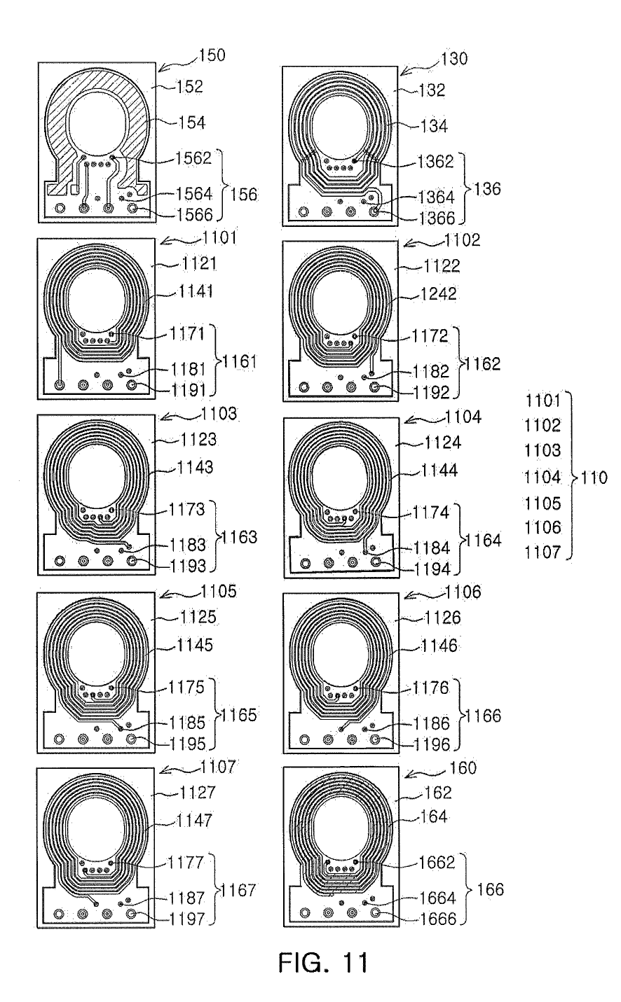

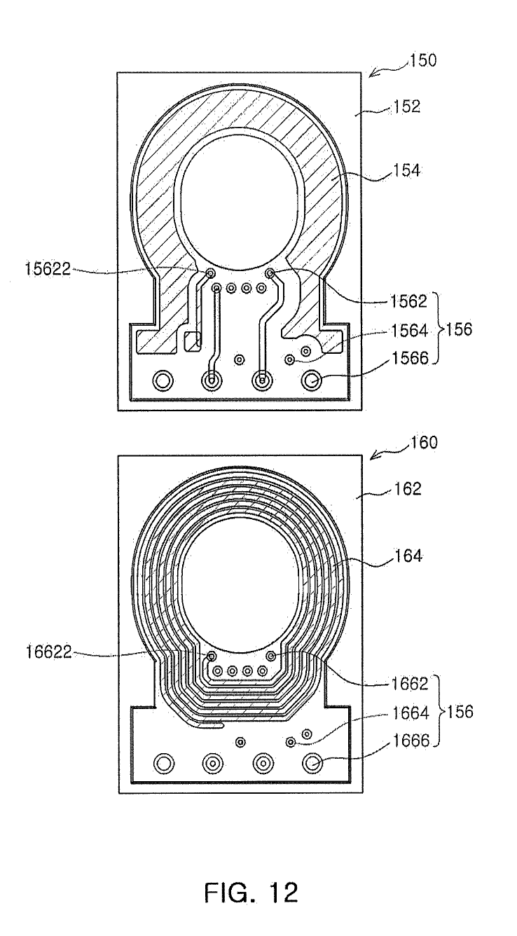

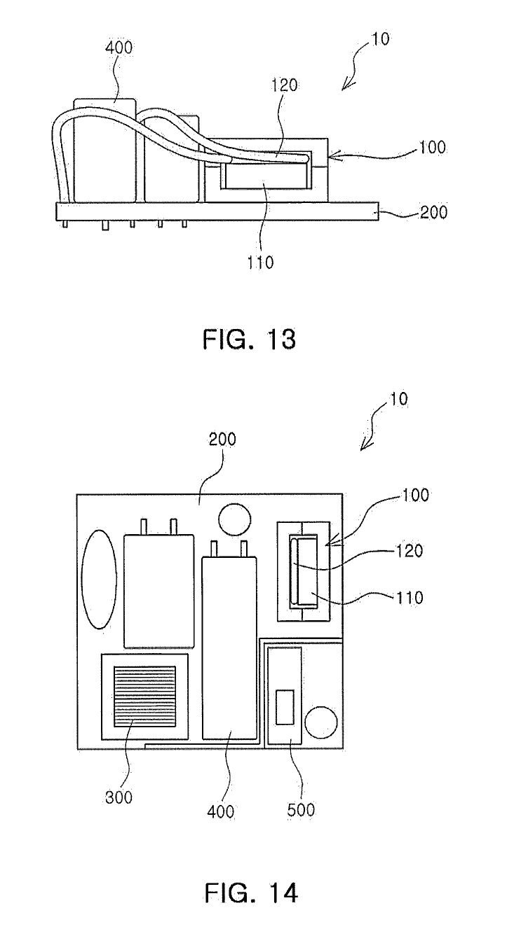

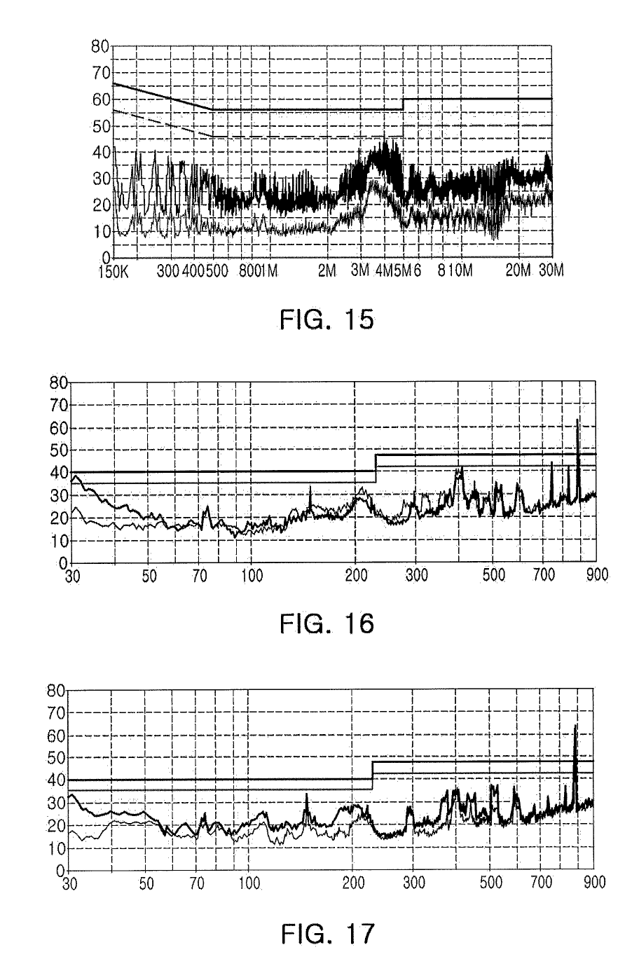

FIG. 1 is an exploded perspective view of a transformer according to an exemplary embodiment of the present disclosure; FIG. 2 is a plan view sequentially illustrating substrates forming a shielding part and a primary coil part illustrated in FIG. 1; FIG. 3 is an enlarged view of the shielding part and a first substrate of the primary coil part illustrated in FIG. 2; FIGS. 4 through 8 are plan views illustrating other forms of the shielding part illustrated in FIG. 2; FIG. 9 is an exploded perspective view of a transformer according to another exemplary embodiment of the present disclosure; FIG. 10 is a plan view sequentially illustrating substrates forming a first shielding part, a tertiary coil part, a primary coil part, and a secondary shielding part illustrated in FIG. 9; FIG. 11 is a plan view illustrating another form of the first shielding part, the tertiary coil part, the primary coil part, and the secondary shielding part illustrated in FIG. 9; FIG. 12 is an enlarged view of the first shielding part and the second shielding part illustrated in FIG. 11; FIG. 13 is a configuration diagram of an adaptor according to an exemplary embodiment of the present disclosure; FIG. 14 is a configuration diagram illustrating another form of the adaptor illustrated in FIG. 13; and FIGS. 15 through 17 are graphs illustrating performance of the transformer according to an exemplary embodiment of the present disclosure.

### (Transformer)

A transformer according to an exemplary embodiment of the present disclosure will be described with reference to FIGS. 1 through 3.

A transformer 100 according to the present exemplary embodiment may include a primary coil part 110, a secondary coil part 120, a shielding part 140, and a core part 170. In addition, the transformer 100 may further include an insulating coating (not shown) for satisfying a safety standard. For example, the insulating coating may have a form of a tape enclosing a circumference of the core part 170. Alternatively, the insulating coating may be an insulating film attached to the core part 170.

The transformer 100 configured as described above may be used to transform a voltage or a current of external power into a voltage or a current appropriate for an electronic device. For example, the transformer 100 may be used in a portable electronic device or an adaptor for the portable electronic device.

Next, main components of the transformer 100 will be described.

The primary coil part 110 may be manufactured in a plate shape. For example, the primary coil part 110 may have a substrate shape. In detail, the primary coil part 110 may include a plurality of substrates on which coil patterns are formed. Here, the coil turns formed by the coil patterns of the primary coil part 110 may be different from that of coils of the secondary coil part 120. For example, the turn of the coils formed by the primary coil part 110 may be larger from that of the coils of the secondary coil part 120. However, a case opposite to the above-mentioned case may be possible.

The secondary coil part 120 may have a bundle shape in which wires formed of copper or another metal material are wound predetermined times. Here, the wire may be coated with an insulating material. For example, the wire may be coated with a triple insulating material. However, a surface of the wire is not necessarily coated with the insulating material. For example, in the case in which a separate insulating tape is wound between the wires, the insulating coating may be omitted. For reference, in the present exemplary embodiment, the secondary coil part 120 may be formed of a coil coated with a triple insulating material. However, the secondary coil part 120 may be formed of a coil coated with a single insulating material or a double insulating material as long as a safety standard is satisfied.

The shielding part 140 may be manufactured in a substrate shape. For example, the shielding part 140 may be manufactured in a shape that is the same as or similar to that of the primary coil part 110. The shielding part 140 may be formed on the primary coil part 110. For example, the shielding part 140 may be formed integrally with the primary coil part 110 on one surface of the primary coil part 110. Therefore, the shielding part 140 may be formed together with the primary coil part 110 in a process of manufacturing the primary coil part 110.

The shielding part 140 may be disposed between the primary coil part 110 and the secondary coil part 120. In this case, an electromagnetic interference phenomenon occurring between the primary coil part 110 and the secondary coil part 120 may be decreased. In addition, the shielding part 140 may be disposed at an outer side of the primary coil part 110, as illustrated in FIG. 1. In this case, an electromagnetic interference phenomenon occurring from the primary coil part 110 may be decreased. However, the shielding part 140 is not limited to being formed in the position according to the above-mentioned example, but may also be disposed on both surfaces of the primary coil part 110 or be disposed at the center of the primary coil part 110.

The core part 170 may be formed of a material having a ferrite structure. However, a material of the core part 170 is not limited to the ferrite, but may be changed into other material. The core part 170 may include outer legs enclosing outer sides of the primary coil part 110 and the secondary coil part 120 and a central leg penetrating through the center of at least one of the primary coil part 110 and the secondary coil part 120. However, the core part 170 is not limited to having the above-mentioned shape. For example, the core part 170 may have a shape in which it includes only the outer legs.

Next, the primary coil part 110 and the shielding part 140 will be described in detail with reference to FIGS. 2 and 3.

The shielding part 140 and the primary coil part 110 may be manufactured in a substrate shape. For example, the shielding part 140 and the primary coil part 110 may include substrates 142 and 1121, 1122, 1123, 1124, 1125, 1126, and 1127 on which metal patterns are formed, respectively, as illustrated in FIG. 2. Here, all of the substrates 142, 1121, 1122, 1123, 1124, 1125, 1126, and 1127 may have the same size. However, the substrates may have different sizes, if necessary.

The shielding part 140 and the primary coil part 110 may be formed integrally with each other. For example, the substrate 142 of the shielding part 140 and the substrates 1121, 1122, 1123, 1124, 1125, 1126, and 1127 of the primary coil part 110 may be sequentially stacked to form one structure.

Next, the shielding part 140 and the primary coil part 110 formed based on the substrates will be described depending on a stacked sequence.

The shielding part 140 may include the substrate 142, a shielding pattern 144, and a plurality of via electrodes 146. The shielding part 140 configured as described above may be formed on the primary coil part 110 to significantly decrease electromagnetic interference.

The substrate 142 may be formed of prepreg. However, a material of the substrate 140 is not limited to the prepreg. For example, the substrate 142 may also be formed of a material that is easily molded and processed.

The shielding pattern 144 may have an open curved line shape in which a portion thereof is opened. For example, the shielding pattern 144 may have a horseshoe or ring shape. However, the shielding pattern 144 is not limited to having the above-mentioned shape. For example, a shape of the shielding pattern 144 may be changed depending on a coil pattern 1141 of an adjacent substrate (first substrate 1101 based on FIG. 2) of the primary coil part 110. For example, the shielding pattern 144 may have a shape in which it may accommodate an entire coil pattern 1141 of the first substrate 1101 therein.

The shielding pattern 144 may have a predetermined width Ws. Here, the width Ws may be substantially the same of a width W1 of the coil pattern 1141 of the first substrate 1101. However, the width Ws is not necessarily the same as the width W1 of the coil pattern 1141, but may be larger or smaller than the width W1, if necessary (See FIG. 3).

The shielding pattern 144 may have a predetermined area As. Here, the area As may be larger than an area A1 of the coil pattern 1141. However, the area As of the shielding pattern 144 is not necessarily larger than the area A1 of the coil pattern 1141. For example, the area As may be increased or decreased as long as shielding performance of the shielding part 140 is ensured.

The shielding pattern 144 may be connected to the via electrode 146. For example, one end (start portion) of the shielding pattern 144 may be connected to a ground terminal by the via electrode 146. In addition, the other end (finish portion) of the shielding pattern 144 may not be connected to any electrode (that is, the other end of the shielding pattern 144 may be opened). This connection structure of the shielding pattern 144 may allow an electromagnetic wave shielding function to be smoothly performed without having an influence on characteristics of the transformer.

The via electrode 146 may be formed on the substrate 142. For example, the plurality of via electrodes 146 may be formed at an inner side and an outer side of the shielding pattern 144. In the present exemplary embodiment, the via electrode 146 may include a via electrode 1462 for a first pattern, a via electrode 1464 for a second pattern, and a via electrode 1466 for an output. Here, the via electrode 1462 for a first pattern may be formed at the inner side of the shielding pattern, and the via electrode 1464 for a second pattern may be formed at the outer side of the shielding pattern 144. In addition, the via electrode 1466 for an output may be formed at an edge portion of the substrate 142.

The primary coil part 110: 1101, 1102, 1103, 1104, 1105, 1106, and 1107 may include a plurality of substrates. For example, the primary coil part 110 may be formed by sequentially stacking a first substrate 1121 on which a first coil pattern 1141, a second substrate 1122 on which a second coil pattern 1142 is formed, a third substrate 1123 on which a third coil pattern 1143 is formed, a fourth substrate 1124 on which a fourth coil pattern 1144 is formed, a fifth substrate 1125 on which a fifth coil pattern 1145 is formed, a sixth substrate 1126 on which a six coil pattern 1146 is formed, and a seventh substrate 1127 on which a seventh coil pattern 1147 is formed and coupling them to each other.

The substrates 1121, 1122, 1123, 1124, 1125, 1126, and 1127 may have the coil patterns 1141, 1142, 1143, 1144, 1145, 1146, and 1147 formed thereon, respectively. For example, the substrates 1121, 1122, 1123, 1124, 1125, 1126, and 1127 may have the coil patterns 1141, 1142, 1143, 1144, 1145, 1146, and 1147 formed thereon, respectively, wherein the coil patterns may have a coil shape. Here, all of the turns of the coil patterns 1141, 1142, 1143, 1144, 1145, 1146, and 1147 may be the same as each other. However, the turns of the coil patterns 1141, 1142, 1143, 1144, 1145, 1146, and 1147 are not necessarily the same as each other. For example, the turn of at least one of the coil patterns 1141, 1142, 1143, 1144, 1145, 1146, and 1147 may be adjusted in order to allow the turn of the primary coil part 110 to coincide with a set value.

In addition, the substrates 1121, 1122, 1123, 1124, 1125, 1126, and 1127 may have via electrodes 1161, 1162, 1163, 1164, 1165, 1166, and 1167 formed therein, respectively. For example, the substrates 1121, 1122, 1123, 1124, 1125, 1126, and 1127 may have via electrodes 1171, 1172, 1173, 1174, 1175, 1176, and 1177 for a first pattern, via electrodes 1181, 1182, 1183, 1184, 1185, 1186, and 1187 for a second pattern, via electrodes 1191, 1192, 1193, 1194, 1195, 1196, and 1197 for an output that are formed therein, respectively. The respective via electrodes 1161, 1162, 1163, 1164, 1165, 1166, and 1167 may be formed in a form in which they penetrate through the substrate 1121, 1122, 1123, 1124, 1125, 1126, and 1127, respectively.

Therefore, the coil patterns 1141, 1142, 1143, 1144, 1145, 1146, and 1147 formed on different substrates 1121, 1122, 1123, 1124, 1125, 1126, and 1127 may be connected to each other by the via electrodes 1161, 1162, 1163, 1164, 1165, 1166, and 1167, respectively. For example, the respective coil patterns 1141, 1142, 1143, 1144, 1145, 1146, and 1147 may be connected to each other like one curved line by the via electrodes 1161, 1162, 1163, 1164, 1165, 1166, and 1167. In detail, one ends of the respective coil patterns 1141, 1142, 1143, 1144, 1145, 1146, and 1147 may be connected to each other through the via electrodes 1171, 1172, 1173, 1174, 1175, 1176, 1177, 1181, 1182, 1183, 1184, 1185, 1186, and 1187 for one pattern.

Meanwhile, the number of via electrodes 1171, 1172, 1173, 1174, 1175, 1176, 1177, 1181, 1182, 1183, 1184, 1185, 1186, and 1187 for a pattern formed in the respective substrates 1121, 1122, 1123, 1124, 1125, 1126, and 1127 may be equal to or greater than that of substrates 1121, 1122, 1123, 1124, 1125, 1126, and 1127 forming the primary coil part 110. For example, when the primary coil part 110 includes seven substrates, the number of via electrodes for a pattern formed in the respective substrates may be 7 or more. However, the number of via electrodes 1191, 1192, 1193, 1194, 1195, 1196, and 1197 for an output may be arbitrarily selected in a range of 2 or more.

Next, other forms of the shielding part will be described with reference to FIGS. 4 through 8.

A shielding part 140 according to one form may have a structure in which the shielding pattern 144 is connected to the via electrode 146 (See FIG. 4). For example, the shielding pattern 144 may be connected to a ground terminal of a circuit board through the via electrode 146. For reference, although the case in which the shielding pattern 144 is connected to the via electrode 1464 for a second pattern has been illustrated in FIG. 4, the shielding pattern 144 may also be connected to the via electrode 1462 for a first pattern or the via electrode 1466 for an output.

A shielding part 140 according to another form may have the shielding pattern 144 having an extended region (See FIG. 5). For example, the shielding pattern 144 may cover a considerable region of the substrate 142.

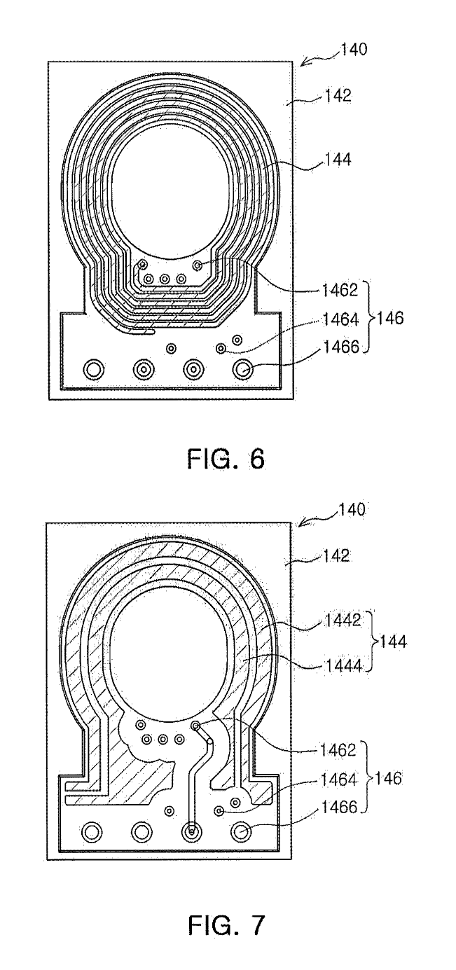

A shielding part 140 according to another form may have the shielding pattern 144 having a coil shape (See FIG. 6). For example, the shielding pattern 144 may have a shape similar to those of the coil patterns 1141, 1142, 1143, 1144, 1145, 1146, and 1147 of the primary coil part 110. That is, the shielding pattern 144 may be formed in a shape in which a single curved line is wound once or more.

A shielding part 140 according to another form may have the shielding pattern 144 formed of a plurality of curved lines (See FIG. 7). For example, the shielding pattern 144 may be formed of two curved lines. That is, the shielding pattern 144 may have a shape in which one curved line is divided into the plurality of curved lines.

The transformer 100 configured as described above may be advantageous in simplifying a manufacturing process or a core assembling process after manufacturing a multilayer printed circuit board (MLB). In addition, a characteristic deviation may be decreased in the transformer 100 according to the present exemplary embodiment as compared with a winding type transformer. Further, in the transformer 100 according to the present exemplary embodiment, a stable characteristic value may be maintained by the shielding part 140, such that electromagnetic interference (EMI) characteristics, which are problems of a plate shaped transformer, may be improved.

Next, a transformer according to another exemplary embodiment of the present disclosure will be described with reference to FIGS. 9 through 12. For reference, in the following description, the same components as those of the transformer according to an exemplary embodiment of the present disclosure described above will be denoted by the same reference numerals and a description thereof will be omitted.

The transformer 100 according to the present exemplary embodiment may be different in a configuration of a shielding part from the transformer 100 according to an exemplary embodiment of the present disclosure described above. For example, the transformer 100 according to the present exemplary embodiment may include a plurality of shielding parts 150 and 160. In detail, the shielding part may include a first shielding part 150 and a second shielding part 160. Here, the first shielding part 150 may be formed on one surface of the primary coil part 110, and the second shielding part 160 may be formed on the other surface of the primary coil part 110.

In addition, the transformer 100 according to the present exemplary embodiment may further include a tertiary coil part 130. For example, the tertiary coil part 130 may be formed between the first shielding part 150 and the primary coil part 110. However, the tertiary coil part 130 is not limited to being formed in the above-mentioned position. For example, the tertiary coil part 130 may be formed between the primary coil part 110 and the second shielding part 160. Alternatively, the tertiary coil part 130 may be formed at an outer side of the first shielding part 150 or an outer side of the second shielding part 160.

The tertiary coil part 130 may include a substrate 132, a coil pattern 134, and a via electrode 136: 1362, 1364, and 1366. That is, the tertiary coil part 130 may have a shape substantially similar to that of the primary coil part 110. The tertiary coil part 130 configured as described above may be formed integrally with the first shielding part 150, the primary coil part 110: 1101, 1102, 1103, 1104, 1105, 1106, and 1107, and the second shielding part 160.

The tertiary coil part 130 configured as described above may be used for the purpose of obtaining induced electromotive force (that is, VCC purpose) from power supplied from the primary coil part 110 or the secondary coil part 120. For example, the tertiary coil part 130 may supply the power obtained from the primary coil part 110 as standby power of an electronic device in which the transformer according to the present exemplary embodiment is mounted. For example, the electronic device may be an adaptor for a portable electronic device.

Next, other forms of the shielding parts 150 and 160 will be described with reference to FIGS. 11 and 12.

The first and second shielding parts 150 and 160 may be connected to each other through via electrodes 156, 136, 1161, 1162, 1163, 1164, 1165, 1166, 1167, and 166. For example, the first shielding part 150 may be connected to a via electrode 1562, and the second shielding part 160 may be connected to a via electrode 1662. Here, since the via electrodes 1562 and 1662 are positioned at positions overlapped with each other in a stacked state, the first and second shielding parts 150 and 160 may be electrically connected to each other.

Meanwhile, the first and second shielding parts 150 and 160 may have different shapes. For example, a shielding pattern 154 of the first shielding part 150 may have a curved line shape in which one side thereof is opened, and a shielding pattern 164 of the second shielding part 160 may have a coil shape in which it is wound twice or more. However, the shielding pattern 154 of the first shielding part 150 and the shielding pattern 164 of the second shielding pattern 160 are not necessarily different from each other. For example, the shielding pattern 154 of the first shielding part 150 and the shielding pattern 164 of the second shielding pattern 160 may have the same shape.

The shielding pattern 154 of the first shielding part 150 and the shielding pattern 164 of the second shielding pattern 160 may be connected to each other. For example, one end of the shielding pattern 154 and one end of the shielding pattern 164 may be connected to each other by the via electrodes 1562 and 1662. In addition, the other end of the shielding pattern 154 and the other end of the shielding pattern 164 may be opened. The shielding parts 150 and 160 having the above-mentioned shielding patterns may smoothly perform a shielding function without having an influence on product characteristics of the transformer.

Therefore, in the transformer 100 according to the present exemplary embodiment, characteristics that are substantially same as or similar to those of an EMI shield using wires may be induced through two shielding parts 150 and 160. In addition, the transformer 100 according to the present exemplary embodiment may be advantageous in simplifying a manufacturing process or a core assembling process after manufacturing an MLB. Further, the transformer 100 according to the present exemplary embodiment may have a characteristic deviation smaller than that of the winding type transformer, such that a stable characteristic value may be maintained. Therefore, in the transformer 100 according to the present exemplary embodiment, EMI characteristics, which are problems of the plate shaped transformer, may be effectively improved.

### (Adapter)

Next, an adapter according to an exemplary embodiment of the present disclosure will be described with reference to FIGS. 13 and 14. For example, a transformer to be described below may be any one of the above-mentioned transformers, and a detailed description thereof will be omitted.

An adaptor 10 according to the present exemplary embodiment may include a transformer 100, a circuit board 200, a filter component 300, a capacitor 400, and a power output terminal 500.

The circuit board 200 may be mounted in the adaptor 10. For example, the circuit board 200 may be mounted in an internal space formed by a case (not shown) of the adaptor 10. In addition, the circuit board 200 may be formed integrally with the case of the adaptor 10. For example, the circuit board 200 may form a portion of the case.

The circuit board 200 may have circuit patterns formed thereon. For example, the circuit board 200 may have the circuit patterns formed thereon in order to connect the transformer 100, the filter component 300, the capacitor 400, and the power output terminal 500 to each other. In addition, the circuit board 200 may have other circuit patterns formed thereon in order to connect other electronic components (for example, a resistor, and the like) to each other, in addition to the above-mentioned electronic components.

the transformer 100 may be mounted on the circuit board 200 so that the substrates 1121, 1122, 1123, 1124, 1125, 1126, and 1127 of the primary coil part 110 thereof are disposed in parallel with the circuit board 200 (See FIG. 13).

Unlike this, the transformer 100 may be mounted perpendicularly to the plane of the circuit board 200. For example, the transformer 100 may be mounted on the circuit board 200 so that the substrates 1121, 1122, 1123, 1124, 1125, 1126, and 1127 of the primary coil part 110 thereof are disposed perpendicularly to the plane of the circuit board 200 (See FIG. 14).

The transformer 100 may be disposed on a corner of the circuit board 200. In addition, the transformer 100 may be disposed in a direction diagonal to the filter component 300. For example, the transformer 100 may be disposed on one corner of the circuit board 200, and the filter component 300 may be disposed on the other corner of the circuit board 200 opposing to one corner thereof (See FIG. 14). This disposition structure may be advantageous in radiating heat generated from coil components (transformer 100 and filter component 300) to the periphery.

In addition, the capacitor 400 may be disposed between the transformer 100 and the filter component 300. This disposition structure may be advantageous in efficiently utilizing a space between the transformer 100 and the filter component 300.

In addition, the transformer 100 may be disposed on the same line as that of the power output terminal 500 on the circuit board 200. This disposition structure may be advantageous in optimizing the circuit patterns of the circuit board 200.

The adaptor 10 according to the present exemplary embodiment configured as described above may be advantageous in maintaining a safety standard of the transformer 100. In addition, the adaptor 10 according to the present exemplary embodiment may be advantageous in miniaturizing a product and be advantageous in improving electromagnetic wave shielding characteristics.

The adaptor 10 according to the present exemplary embodiment has shown substantially excellent EMI characteristics, as illustrated in FIGS. 15 and 17. Particularly, in the case in which the shielding parts 150 and 160 of the transformer 100 are connected to the core, more excellent EMI characteristics were shown. In addition, in which a snubber circuit is configured in the adapter 10, a leakage phenomenon was decreased. For reference, in the present exemplary embodiment, the snubber circuit may include a chip resistor and a multilayer ceramic capacitor (MLCC).

As set forth above, according to exemplary embodiments of the present disclosure, a transformer capable of being easily miniaturized may be provided.

In addition, according to exemplary embodiments of the present disclosure, an adaptor capable of being miniaturized may be provided.

While exemplary embodiments have been shown and described above, it will be apparent to those skilled in the art that modifications and variations could be made without departing from the spirit and scope of the present disclosure as defined by the appended claims.

What is claimed is:

1. A transformer comprising:
a primary coil part including a multilayer substrate in which a plurality of substrates having coil patterns are stacked;
a secondary coil part having the number of coil turns different from that of the primary coil part, positioned on at least one of upper and lower surfaces of the multilayer substrate, and including a conductor wire and an insulating material coating the conductor wire; and
a shielding part disposed on the primary coil part and including at least one substrate on which a shielding pattern is provided.

2. The transformer of claim 1, wherein an area of the shielding pattern is equal to or larger than that of the coil pattern of the primary coil part adjacent to the shielding pattern.

3. The transformer of claim 1, wherein a width of a curved portion of the shielding pattern is different from that of a curved portion of the coil pattern of the primary coil part adjacent to the shielding pattern.

4. The transformer of claim 1, wherein the shielding pattern has an open curved line shape in which a portion thereof is opened.

5. The transformer of claim 1, wherein the shielding pattern is disposed in parallel to edges of the substrate of the shielding part.

6. The transformer of claim 1, wherein the shielding pattern is formed of a single curved line having a coil shape.

7. The transformer of claim 1, wherein the shielding pattern is formed of a plurality of curved lines having a coil shape.

8. The transformer of claim 1, wherein the shielding pattern is connected to the coil pattern of the primary coil part.

9. The transformer of claim 1, wherein the shielding pattern is connected to a core part.

10. The transformer of claim 1, wherein the shielding part includes:
a first shielding part disposed on one side of the primary coil part; and
a second shielding part disposed on the other side of the primary coil part.

11. The transformer of claim 10, wherein the first shielding part is connected to the second shielding part by a via electrode penetrating through the primary coil part.
